(19) United States
(12) Patent Application Publication
(10) Pub. No.: US 2013/0234011 A2
(43) Pub. Date: Sep. 12, 2013

(54) METHOD FOR SETTING AN OPERATING PARAMETER OF A PARTICLE BEAM DEVICE AND A SAMPLE HOLDER FOR PERFORMING THE METHOD

(71) Applicants: Harald Niebel, Oberkochen (DE); Giuseppe Pavia, Aalen (DE); Heiko Stegmann, Dresden (DE); Richard Schillinger, Konigsbronn (DE)

(72) Inventors: Harald Niebel, Oberkochen (DE); Giuseppe Pavia, Aalen (DE); Heiko Stegmann, Dresden (DE); Richard Schillinger, Konigsbronn (DE)

(21) Appl. No.: 12/655,635

(22) Filed: Jan. 4, 2010

(30) Foreign Application Priority Data
Jan. 6, 2009 (DE) 10 2009 000 041.0
Mar. 16, 2009 (DE) 10 2009 001 587.6

(51) Int. Cl. H01J 37/20; H01J 37/26; G12B 13/00

(52) U.S. Cl. 250/252.1; 250/442.11; 250/307

(57) ABSTRACT

A method for adjusting an operating parameter of a particle beam device and a sample holder, which is suitable in particular for performing the method are provided. An adjustment of an operating parameter of a particle beam device is possible without transfer of the sample holder out of the particle beam device. A reference sample is placed in a first sample receptacle, so that in ongoing operation of the particle beam device, the sample holder need only be positioned in such a way that the reference sample is bombarded and measured with the aid of a particle beam generated in the particle beam device.

### TECHNICAL FIELD

This application relates to particle beam devices and, more particularly, to a method for setting an operating parameter of a particle beam device as well as to a sample holder, which is suitable in particular for performing the method.

### BACKGROUND OF THE INVENTION

Particle beam devices, e.g., electron beam devices, have long been known for examining samples. In particular scanning electron microscopes and transmission electron microscopes are known. With a transmission electron microscope, electrons generated by a beam generator are directed at a sample to be examined. The electrons of the electron beam are scattered in the sample. The scattered electrons are detected and used to generate images and diffraction patterns.

It is known that one or more samples to be examined may be placed on a single sample holder, which is then transferred to the transmission electron microscope for examining the one or more samples. The known sample holder is designed with a rod shape having a first end and a second end, the one or more samples to be examined being placed at the first end.

Furthermore, it is known from the prior art that several sample receptacles may be provided on the sample holder, each being tiltable in relation to the sample holder. A sample holder provided with a sample receptacle which is heatable or coolable is also known.

With regard to the prior art cited above, reference is made to U.S. Pat. No. 5,698,856 as well as pages 124 to 128 of the book Transmission Electron Microscopy, Vol. 1 by David B. Williams and C. Barry Carter, 1996, which are both incorporated herein by reference.

Sample holders whose sample receptacle(s) is/are situated immovably in relation to the sample holder (i.e., to, assume a nonadjustable position in relation to the sample holder) are a disadvantage because they are not very suitable for examining crystalline samples. With these sample holders, it is essential that samples situated in the sample receptacle(s) may be examined from various angles by the electron beam to obtain information about the crystal structure of the sample(s).

Furthermore, it is known that with a transmission electron microscope, it may be necessary to calibrate a guidance device for the electron beam, e.g., an electromagnetic and/or electrostatic device in the form of a so-called corrector, at certain intervals. The aforementioned corrector is used in particular in a transmission electron microscope to correct a spherical aberration (Cₛ) and/or a chromatic aberration (C_{c}) of an objective lens of the transmission electron microscope. Reference is made here to DE 199 26 927 A1 as an example, which is incorporated herein by reference.

To achieve a sufficiently good and reproducible image quality, it is necessary to calibrate the corrector at predefinable intervals of time. To do so, in the past a reference object (hereinafter also referred to as a reference sample) has been placed on a sample holder known from the prior art and transferred to a sample area of the transmission electron microscope, which is kept under vacuum. Next the calibration is performed. After successful calibration, the sample holder is transferred out of the sample area of the transmission electron microscope, and the reference object is removed from the sample holder. In another step, one or more samples to be examined are then placed on the sample holder. The sample holder is next transferred to the sample area of the transmission electron microscope. The procedure described above from the prior art has the disadvantage that it is very time-consuming because transfer of the sample holder into the sample area of the transmission electron microscope, which is kept under vacuum, and transfer out of the sample area take a certain amount of time. Since it may be necessary to perform a renewed calibration of the corrector after a certain operating time of the transmission electron microscope, the procedure described above must be performed again. Renewed transfer into and out make the method described above even more time-consuming.

Accordingly, it would be desirable to provide a method and a sample holder with which it is not absolutely necessary to transfer the sample holder out to adjust an operating parameter of a particle beam device.

### SUMMARY OF THE INVENTION

According to the system described herein, a method is provided to adjust at least one operating parameter of a particle beam device, e.g., an operating parameter of a corrector and/or a stigmator of a transmission electron microscope. Furthermore, the method may also be used to correct an operating parameter of a device for illuminating a sample in a scanning transmission electron microscope. Reference is made explicitly to the fact that the aforementioned examples are not conclusive. Instead, the method according to the system described herein is suitable for adjusting any operating parameter of any particle beam device.

In the method according to the system described herein, a sample holder having at least one first sample receptacle for receiving a reference sample and having at least one second sample receptacle for receiving a sample to be examined with the aid of a particle beam in a particle beam device may be used. In this method, a reference sample may be placed on the first sample receptacle. In addition, a sample to be examined with the aid of a particle beam may be placed on the second sample receptacle. The sample holder may be moved in such a way that the particle beam strikes the reference sample in the first sample receptacle. By examining the reference sample with the aid of the particle beam and/or through the examination results obtained, at least one operating parameter of the particle beam device may be adjusted. Following that, the sample holder may be moved in such a way that the particle beam strikes the sample to be examined in the second sample receptacle. The sample to be examined may then be examined with the aid of the particle beam.

It is pointed out explicitly that the method according to the system described herein may also be performed if, instead of the sample holder, the particle beam is moved in such a way that it strikes the reference sample or the sample to be examined. In an embodiment, the sample holder may move only in relation to the particle beam.

The method according to the system described herein has the advantage that at least one operating parameter of a particle beam device, e.g., a transmission electron microscope, may be adjusted without transferring the sample holder out of the sample area of the particle beam device, which may be kept under vacuum. This method makes it possible to place a reference sample on the first sample receptacle so that in ongoing operation of the particle beam device the sample holder need be positioned relatively only in such a way that the reference sample is bombarded and measured using the particle beam generated in the particle beam device. It is possible in this way to adjust at least one operating parameter of at least one component of the particle beam device so that sufficiently good functioning of this component is achieved in this way. This yields a sufficiently good and reproducible image quality.

In an embodiment of the method according to the system described herein, after placing the reference sample on the first sample receptacle and/or placing the sample to be examined on the second sample receptacle, the sample holder may be transferred into the particle beam device. In an alternative embodiment, this is not necessary because in this alternative embodiment the reference sample may be placed on the first sample receptacle and/or the sample to be examined may be placed on the second sample receptacle inside the particle beam device instead of outside the particle beam device.

According to another embodiment of the method according to the system described herein, the sample holder position may be adjusted by rotating the sample holder by a predefinable angle, starting from an initial position of the sample holder in a first sample holder direction and/or in a second sample holder direction. Alternatively or additionally, the sample holder may be moved along a first axis, a second axis and a third axis, wherein the first axis, the second axis and the third axis are each perpendicular to one another, and the third axis is oriented parallel to an optical axis of the particle beam device.

The sample holder may be rotated about at least one of the following axes, for example: the first axis, the second axis and the third axis. For example, the sample holder may be rotated by an angle of 0° to 180°, in particular 0° to 90°. As already mentioned above, the sample holder may be rotatable by the predefinable angle, starting from the initial position of the sample holder, in the first sample holder direction and/or in the second sample holder direction. Therefore, this means that with the aforementioned exemplary embodiment, rotation by an angle of 0° to 180° is possible in the first sample holder direction and also in the second sample holder direction.

Furthermore, in another embodiment of the method in which the sample holder having a movable second sample receptacle is used, it is provided that an examining position may be adjusted by moving the second sample receptacle in relation to the sample holder. It is provided in particular that the examination position of the second sample receptacle may be adjusted by rotating the second sample receptacle by an angle of 0° to 180°, preferably 20° to 160°, starting from an initial position of the second sample receptacle. Alternatively or additionally, the examination position of the second sample receptacle may be adjusted by rotating the second sample receptacle in a first direction and/or in a second direction, each by an angle of 0° to 90°, starting from the initial position of the second sample receptacle. The aforementioned exemplary embodiments are suitable for measuring crystalline samples in particular, as described in greater detail below.

As already mentioned above, the method according to the system described herein may be used in particular for calibrating an electromagnetic and/or electrostatic device of the particle beam device, in particular a corrector of a transmission electron microscope.

In another embodiment of the method according to the system described herein, the sample placed in the second sample receptacle may be brought to a certain temperature by heating or cooling. For example, the sample placed in the second sample receptacle may be cooled to a temperature of approximately −173° C. or heated to a temperature of approximately 1000° C.

The method according to the system described herein may be used with any suitable particle beam device, including in particular the aforementioned transmission electron microscope (TEM), a scanning transmission electron microscope (STEM), an energy-filtered transmission electron microscope (EFTEM) and an energy-filtered scanning transmission electron microscope (EFSTEM). The list given here is not exclusive but is to be understood only as an example.

The system described herein also relates to a sample holder. The sample holder according to the system described herein may be provided for holding a sample to be examined with the aid of a particle beam. Furthermore, it may be provided for use in a method having at least one of the aforementioned features or a combination of several of the aforementioned features. According to the system described herein, the sample holder may assume a predefinable sample holder position. Furthermore, the sample holder may have at least one first sample receptacle, which may be immovable in relation to the sample holder. The first sample receptacle may thus be fixedly attached on the sample holder and cannot move in relation to the sample holder. Furthermore, the sample holder may be provided with at least one second sample receptacle, which may be movable in relation to the sample holder, in contrast with the first sample receptacle, to assume an examination position.

Another sample holder according to the system described herein may also be provided for holding a sample to be examined with the aid of a particle beam. This sample holder may also be provided for use in a method having at least one of the aforementioned features or a combination of several of the aforementioned features. This sample holder may again be movable to assume a predefinable sample holder position. Furthermore, the sample holder may have at least one first sample receptacle, which may be immovable in relation to the sample holder. The first sample receptacle may thus be fixedly attached on the sample holder and cannot move in relation to the sample holder. Furthermore, the sample holder may be provided with a second sample receptacle, which may have a device for adjusting a predefinable temperature of a sample that may be held in the second sample receptacle.

The system described herein also relates to another sample holder, which may also be provided for holding a sample to be examined with the aid of a particle beam. This sample holder may also be provided for use in a method having at least one of the aforementioned features or a combination of several of the aforementioned features. This sample holder may be movable to assume a predefinable sample holder position. Furthermore, the sample holder may have at least one holding device, which may be movable in relation to the sample holder to assume an examination position. Furthermore, the holding device may have at least one first sample receptacle to receive a reference sample and at least one second sample receptacle to receive a sample to be examined.

The system described herein also relates to another sample holder which may also be provided for holding a sample to be examined with the aid of a particle beam. This sample holder may also be provided for use in a method having at least one of the aforementioned features or a combination of several of the aforementioned features. With this sample holder according to the system described herein, a grid-type holding device having a plurality of openings may be provided, at least one first opening and at least one second opening being separated from one another by at least one dividing web. The holding device, for example, may have a lattice structure with a plurality of meshes (openings) and dividing webs. The holding device, however, is not limited to a certain grid-type design. Instead, any grid-type design may be provided, e.g., a honeycomb design and/or a grid-type design in which the openings are designed to be circular. The holding device of this sample holder according to the system described herein may have at least one first sample receptacle to receive a reference sample and at least one second sample receptacle to receive a sample to be examined.

The sample holders according to the system described herein have the same advantage already described above: it is possible to adjust at least one operating parameter of a particle beam device, e.g., a transmission electron microscope, without transferring one of the sample holders out of the sample area of the particle beam device, which may be kept under a vacuum. With the sample holders, it is possible to place a reference sample on the first sample receptacle, so that in ongoing operation of the particle beam device, the sample holder need be positioned only in such a way that the reference sample is bombarded and measured using a particle beam generated in the particle beam device.

The sample holder according to the system described herein, whose second sample receptacle may be movable in relation to the sample holder, also makes it possible to measure a crystalline sample sufficiently well by examining it at various angles of incidence of the particle beam on the crystalline sample.

If reference is made to the sample holder below, this always refers to all the aforementioned sample holders unless explicitly mentioned otherwise.

In an embodiment of the sample holder according to the system described herein, which has the movably designed second sample receptacle, it is additionally possible to provide for this embodiment to have a device for adjusting a predefinable temperature of a sample receivable in the second sample receptacle.

As already mentioned above, the first sample receptacle of the sample holder may be provided to receive a reference sample, for example. The second sample receptacle may be provided to receive a sample to be examined. The system described herein of course may also relate to all sample holders with which a reference sample has already been provided on the first sample receptacle and a sample to be examined has already been provided on the second sample receptacle.

In another embodiment of the system described herein, the sample holder may be movable along a first axis, a second axis and a third axis, wherein the first axis, the second axis and the third axis are each situated perpendicular to one another. The third axis may be parallel to an optical axis of the particle beam device. In addition, in another embodiment, it is provided that the sample holder may be rotatable about at least one of the following axes: the first axis, the second axis and the third axis. Rotation may take place by an angle of 0° to 180°, for example, or from 0° to 90°, for example; the rotation may take place in two directions, as already described above. In an embodiment, the sample holder may be movable in a translatory movement along a first axis in the x direction, a second axis in the y direction and a third axis in the z direction, each being perpendicular to the others. In addition, the sample holder may be rotatable about the first axis in the x direction. In an embodiment, the sample holder may be placed on a goniometer, which moves the sample holder by translatory and/or rotational movement.

In another embodiment of the sample holder according to the system described herein, the second sample receptacle, which may be movable, is rotatable about a receptacle axis, wherein the receptacle axis, starting from an initial position of the second sample receptacle, may be situated in or parallel to a plane spanned by two of the following axes: the first axis, the second axis, and the third axis. It is provided in particular that the second sample receptacle, starting from the initial position of the second sample receptacle, may be rotatable by an angle of 0° to 180°, in particular 0° to 90°. As explained below, the rotation may be in two directions. In another embodiment, the receptacle axis may run perpendicular to a longitudinal axis of the sample holder, and the second sample receptacle, starting from the initial position of the second sample receptacle, may be rotatable in a first direction and/or in a second direction at an angle of 0° to 90°. It is pointed out explicitly that the system described herein is not restricted to the aforementioned angles (or angle ranges). Instead, any angle suitable for examining a sample may be selected.

In another embodiment of the sample holder according to the system described herein, a mechanical and/or electronic adjustment device may be provided on the sample holder for adjusting the examination position. It is provided in particular that the adjustment device may have a sprocket wheel mechanism; however, the adjustment device is not limited to a sprocket wheel mechanism. Instead, any suitable adjustment device may be selected, e.g., including an adjustment device having a belt gear and/or an eccentric disc.

With the sample holder according to the system described herein having the grid-type holding device, in an alternative embodiment, the holding device may be provided with a surface having a recess. The sample to be examined may be received in this recess. In another embodiment, the ratio of the area to the recess may have a value of 5:1 to 3:1.

### BRIEF DESCRIPTION OF THE DRAWINGS

Embodiments of the system described herein are explained in greater detail below based on the figures, which are briefly described as follows:

FIG. 1 shows a schematic view of a transmission electron microscope according to an embodiment of the system described herein;

FIG. 2 shows a schematic view of another transmission electron microscope according to an embodiment of the system described herein;

FIG. 3 shows a schematic view of a sample holder according to an embodiment of the system described herein;

FIG. 4 shows another schematic view of a sample holder according to FIG. 3;

FIG. 5 shows a schematic view of the sample holder according to FIG. 3 having a movable second sample receptacle;

FIG. 6 shows a schematic view of the sample holder according to FIG. 3 having a heating and cooling device;

FIG. 7A shows a schematic view of another sample holder according to an embodiment of the system described herein;

FIG. 7B shows a schematic view of another sample holder according to an embodiment of the system described herein;

FIG. 8 shows a flow chart of a method for adjusting an operating parameter of a particle beam device according to an embodiment of the system described herein;

FIG. 8A shows an intermediate step of the method according to FIG. 8; and

FIG. 9 shows another intermediate step of the method according to FIG. 8.

### DETAILED DESCRIPTION OF VARIOUS EMBODIMENTS

The system described herein is explained in particular on the basis of a particle beam device in the form of a transmission electron microscope (hereinafter referred to as TEM). However, it is already pointed out here that the system described herein is not limited to a TEM, but instead the system described herein may also be used with any particle beam device suitable for receiving the sample holder according to the system described herein and/or for performing the method according to the system described herein.

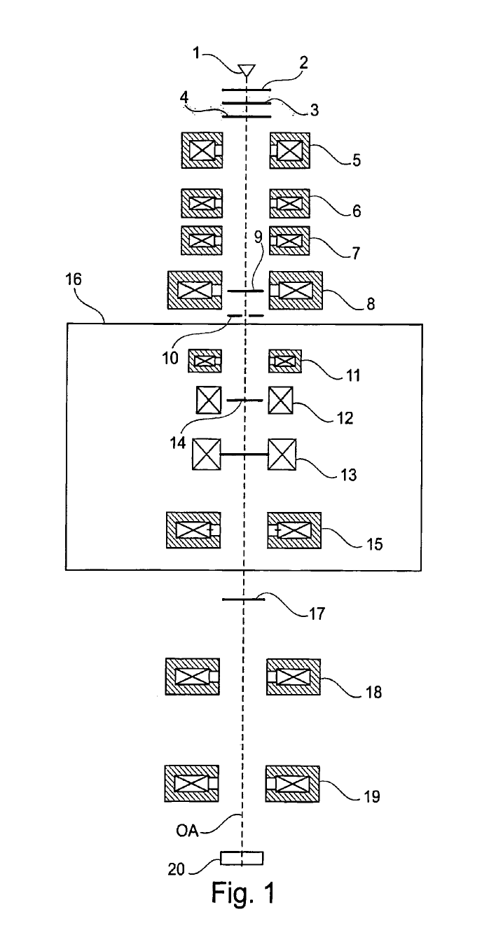

FIG. 1 shows a schematic view of a TEM 100 according to an embodiment of the system described herein. The TEM 100 may have an electron source 1 in the form of a thermal field emission source. However, another electron source may also be used. Along optical axis OA of the TEM 100, an extraction electrode 2, whose potential extracts electrons from electron source 1, may be situated downstream from the electron source 1. Furthermore, a first electrode 3 may be provided for focusing the source position, and at least one second electrode 4 in the form of an anode may be provided for accelerating the electrons. Because of the second electrode 4, the electrons coming from the electron source 1 may be accelerated with the aid of an electrode voltage to a desired and adjustable energy.

In the remaining length on optical axis OA, a multistage condenser may be provided, having three magnetic lenses 5 to 7 (namely a first magnetic lens 5, a second magnetic lens 6 and a third magnetic lens 7), to which an objective 8 in the form of a magnetic lens may be arranged. An object plane 9 on which a sample to be examined may be placed with the aid of a sample manipulator may be provided on the objective 8. In particular, the illuminated field of the object plane 9 may be adjustable through appropriate adjustment of the operating parameters (for example, a lens current) of the first magnetic lens 5, the second magnetic lens 6, the third magnetic lens 7 and the objective 8.

A corrector 16 having several units described below may be situated downstream from the objective 8 in the opposite direction from the electron source 1. The corrector 16 may be used to correct a spherical aberration (CO of the objective 8. The corrector 16 may have a first transfer lens 11 embodied as a magnetic lens. The first transfer lens 11 may image a rear focal plane of the objective 8. Furthermore, the first transfer lens 11 may generate a real intermediate image 14 of the object plane 9. A first correction system 12 in the form of a multipole may be provided in the plane of the intermediate image 14 generated by the first transfer lens 11. A second correction system 13 in the form of another multipole and a second transfer lens 15 may be connected downstream from the first correction system 12. The second transfer lens 15 may image the intermediate image 14 of the object plane 9 in an input image plane 17 of a projector system including lenses 18 and 19. The projector system 18, 19 may then generate an image on a detector 20 of the sample situated in the object plane 9 and imaged in the input image plane 17 of the projector system 18, 19.

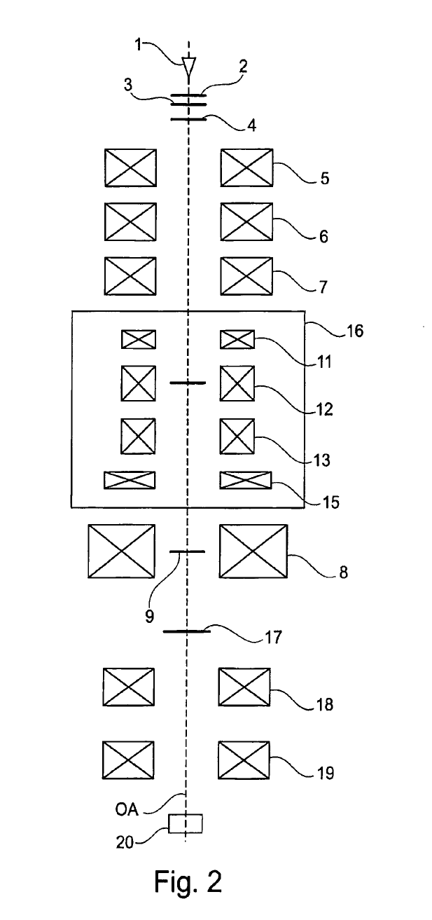

FIG. 2 shows a schematic view of another embodiment of a particle beam device according to the system described herein, wherein FIG. 2 shows a scanning transmission electron microscope (STEM) 101. The same components are labeled with the same reference numerals. The particle beam device according to FIG. 2 differs in principle from the particle beam device according to FIG. 1 only in that the corrector 16 may be situated upstream from the objective 8.

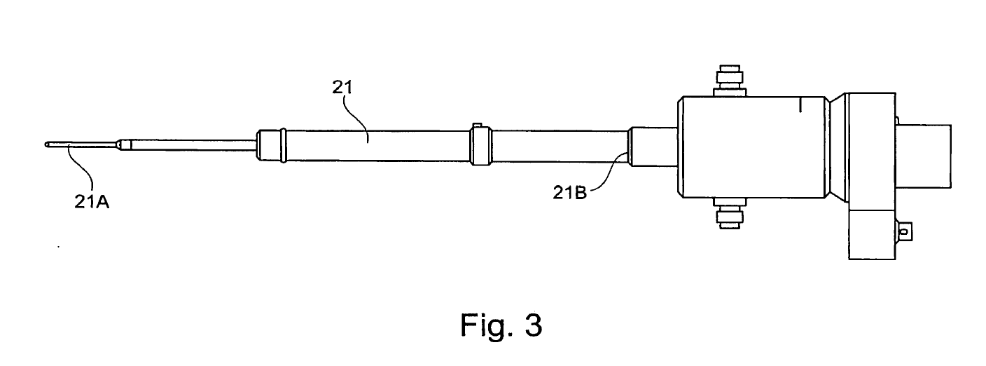

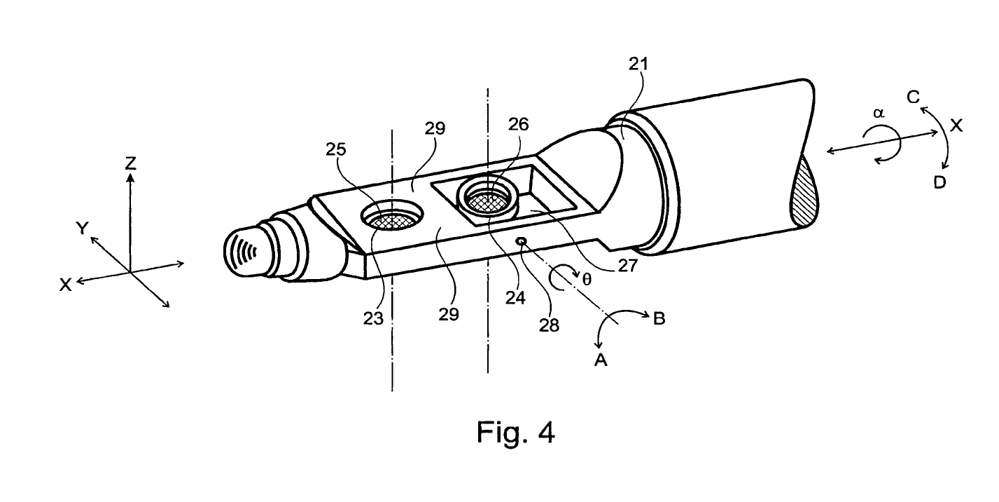

FIG. 3 shows a schematic view of a rod-shaped sample holder 21 having a longitudinal axis and provided with a first end 21A and a second end 21B according to an embodiment of the system described herein. Samples are situated at the first end 21A, as is explained further below. FIG. 4 shows the first end 21A of the sample holder 21 in a somewhat enlarged view. The sample holder 21 may be situated on a goniometer, which may be used to move the sample holder 21 in a translatory and/or rotational manner. Situating the sample holder 21 in a goniometer is known from the prior art. Reference is made to DE 35 46 095 A1 as an example, which is incorporated herein by reference. For this reason, the details of the arrangement of the sample holder 21 in the goniometer will not be given here. With the goniometer, it is possible to move the sample holder 21 along a first axis in x direction (x axis), along a second axis in y direction (y axis) and along a third axis in z direction (z axis). The first axis (x axis), the second axis (y axis) and the third axis (z axis) are each perpendicular to one another. In addition, it is possible to rotate the sample holder 21 about the first axis (x axis), for example, by a predefinable angle α (cf. also FIG. 4).

A first sample receptacle 23 may be provided on the sample holder 21 and may be fixedly attached to thereto. The first sample receptacle 23 may therefore not be movable in relation to the sample holder 21. A reference sample 25 may be placed in the first sample receptacle 23.

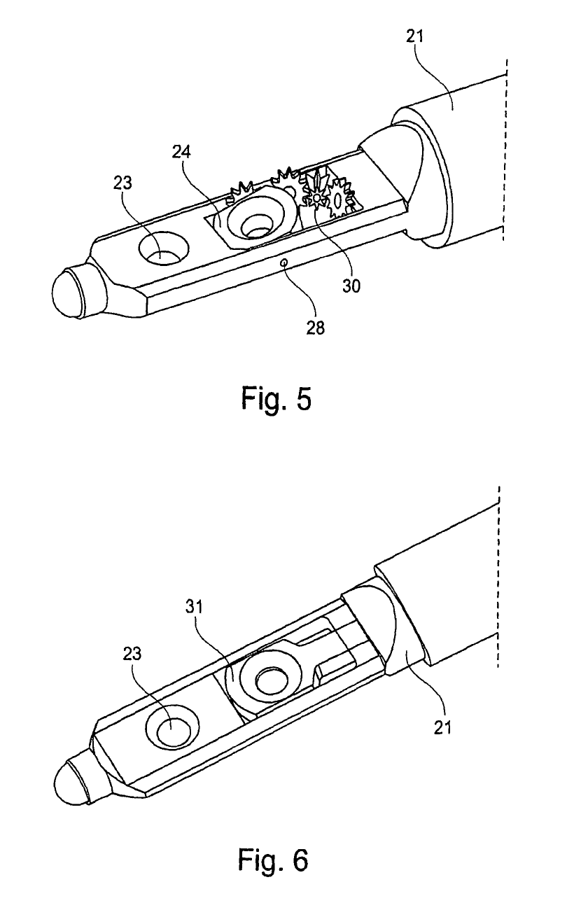

A second sample receptacle 24, in which a sample 26 to be examined is accommodated, may be situated in the direction of the longitudinal axis of the sample holder 21 a distance away from the first sample receptacle 23. The second sample receptacle 24 may be arranged in a recess 27 in the sample holder 21 and may be rotatable about a receptacle axis 28. The second sample receptacle 24 may thus be movable in relation to the sample holder 21. The receptacle axis 28 may run perpendicular to the longitudinal axis of the sample holder 21. The second sample receptacle 24, starting from an initial position, may be rotatable by an angle 0 of 0° to 90° in a first direction A and/or a second direction B. In this embodiment, the initial position may be defined by the fact that a surface of the sample 26 to be examined may be situated essentially parallel to a surface 29 of the sample holder 21. The second sample receptacle 24 may be rotated by a sprocket wheel device 30, for example, which is shown schematically in FIG. 5. However, the system described herein is not limited to the sprocket wheel device 30. Instead, any mechanical and/or electronic device suitable for moving the second sample receptacle 24 in relation to the sample holder 21 by rotation about the receptacle axis 28 to assume predefinable examination positions may be used.

As already mentioned above, the sample holder 21 may be rotatable about the first axis (x axis). In this embodiment, starting from an initial position, the sample holder 21 may be movable in a first sample holder direction C and in a second sample holder direction D, each by an angle α of 0° to 90°.

FIG. 6 shows an alternative embodiment of sample holder 21 corresponding essentially to the sample holder 21 already described above. In contrast with the latter, the sample holder 21 shown in FIG. 6 may have a second sample receptacle 31, which may be provided with a cooling and/or heating device. It is thus possible to bring the sample held in the second sample receptacle 31 to a certain temperature. In addition to this, the second sample receptacle 31 of FIG. 6 may be movable in exactly the same way as the second sample receptacle 24 of FIG. 4.

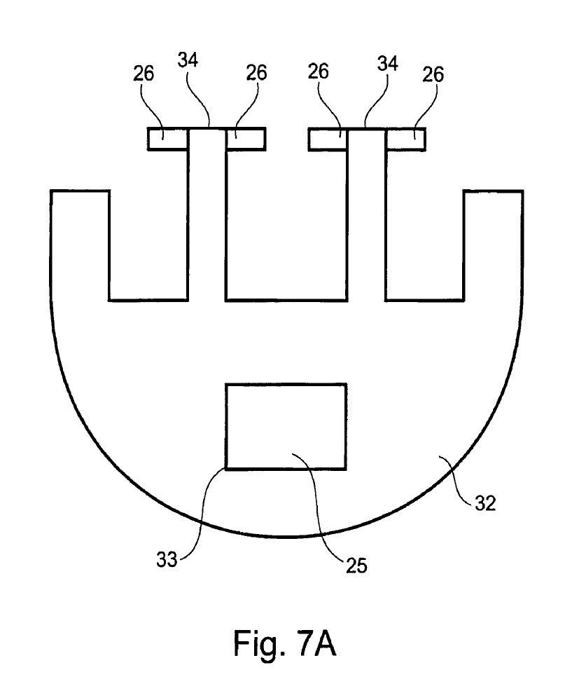

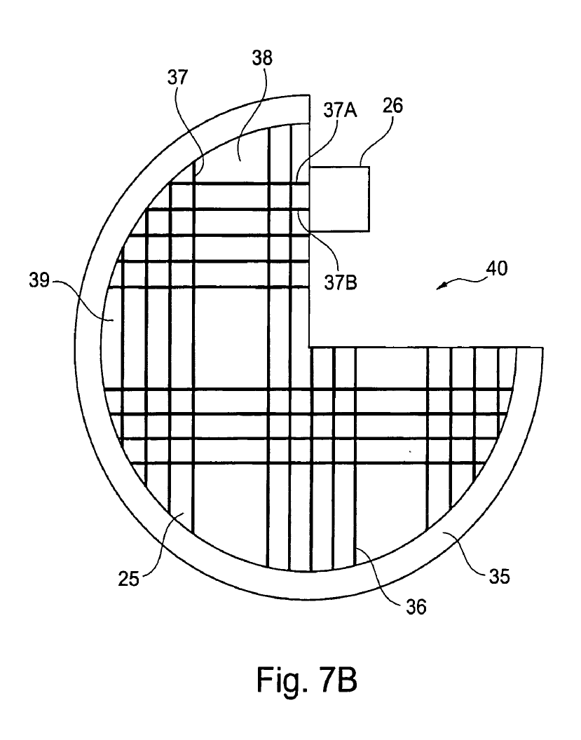

FIG. 7A shows an alternative exemplary embodiment of a holding device 32 for a sample, the holding device 32 being used with the sample holder 21 according to FIG. 4, as explained in greater detail below. The holding device 32 in this embodiment may be made of a copper carrier and may have a first sample receptacle 33, which receives a reference sample 25. Furthermore, the holding device 32 of this embodiment may be provided with two second sample receptacles 34 extending from a base element of the holding device 32. The samples 26, which are to be examined and are embodied in a lamellar form extending laterally from the second sample receptacles 34, may be situated on an exposed end of each of the second sample receptacles 34.

Instead of the sample 26 to be examined, the holding device 32 may thus be inserted into the second sample receptacle 24 of the sample holder 21. It may thus be adjustable in the directions of movement exactly as already explained above and as illustrated in FIG. 4. The reference sample 25 and the sample 26 to be examined may be moved in particular when the holding device 32 rotates in direction A or B about the receptacle axis 28. In an embodiment, since the holding device 32 may usually have a diameter or a longitudinal extent of approximately 3 mm and since the sample 26 to be examined and the reference sample 25 may be situated in the range of less than 2 mm apart from one another, in order to examine the reference sample 25 or the sample 26 to be examined, the travel distances of the sample holder 21 may not be very great (as explained in greater detail below).

In another embodiment, in addition to the holding device 32 described here, the reference sample 25 may be left in the first sample receptacle 23 of the sample holder 21. Thus, in this embodiment, the reference sample 25 may be provided in the first sample receptacle 23 of the sample holder 21 and also in the first sample receptacle 33 of the holding device 32. In yet another embodiment of the system described herein (not shown here), no reference sample 25 is provided in the first sample receptacle 23 of the sample holder 21 but instead may be provided only in the holding device 32. In another alternative embodiment, the holding device 32 may be situated in a sample holder having only a single sample receptacle (not shown here). Furthermore, in yet another embodiment, holding device 32 is situated in the first sample receptacle 23 of the sample holder 21 (instead of the reference sample 25).

FIG. 7B shows another exemplary embodiment of a holding device 35 for a sample, wherein the holding device 35 may be used with the sample holder 21 according to FIG. 4, as explained in greater detail below. The holding device 35 may have a grid-type design and may be provided with a grid 36 made of webs 37 and meshes 38. The meshes 38 may be openings in the grid-type design. The holding device 35 may be covered over its surface with a carbon film 39 and may have a recess 40 in the surface corresponding essentially to one-quarter of the total surface area of the holding device 35. The reference sample 25 may be applied on the carbon film 39 or at least partially on the carbon film 39. Alternatively or additionally, it is provided that the carbon film 39 may itself be the reference sample 25. In this embodiment, the sample 26 to be examined may also be provided. The sample 26 may be situated in the recess 40 on a first web 37A and on a second web 37B, which border the recess 40. The holding device 35 described here may be inserted into the second sample receptacle 24 on the sample holder 21 of FIG. 4 instead of the sample 26 to be examined and may be, movable as described above. In addition, the same alternative exemplary embodiments may also be provided for the holding device 35 as for the holding device 32 of FIG. 7A.

The exemplary embodiments described here having the sample holder 21 may be suitable in particular for performing the method, which is described in greater detail below.

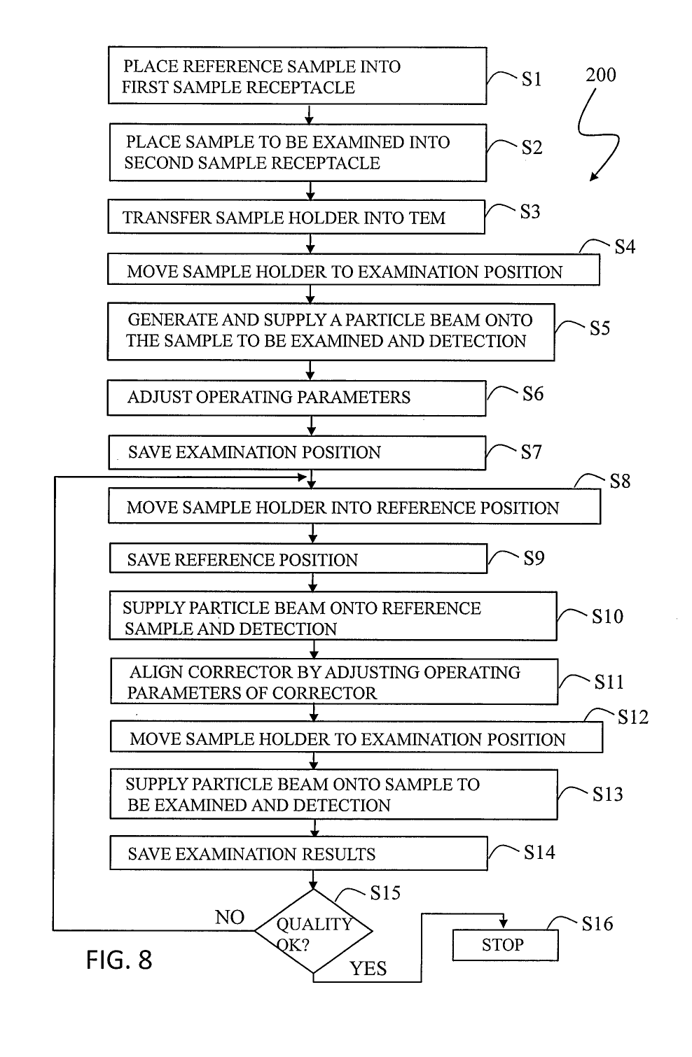

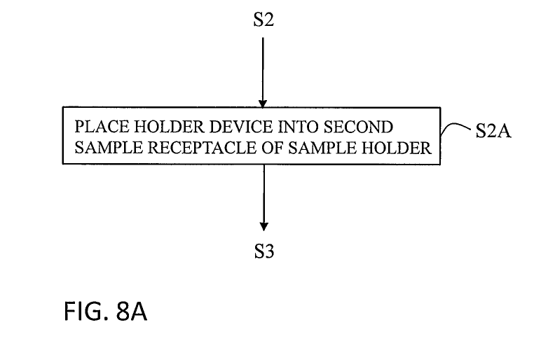

FIG. 8 is a flow chart 200 showing steps of a method according to an embodiment of the system described herein, in which the sample holder 21 according to FIG. 4 described above may be used. This method may be used in the TEM 100, for example. However, it may also be used in other particle beam devices, e.g., in the EFTEM or STEM 101 already mentioned above. In the method shown here, a correction of the corrector 16, which is used to correct the spherical aberration (CO, may be performed.

In a method step S1, the first reference sample 25 may be placed on the first sample receptacle 23 of the sample holder 21. Next the sample 26 to be examined with the aid of the electron beam of the TEM 100 may be placed on the second sample receptacle 24 (method step S2).

After the placement in method steps S1 and S2, the sample holder 21 may be transferred into the TEM 100 in the area of the object plane 9 (method step S3).

In a next method step S4, the sample holder 21 may be moved, so that the second sample receptacle 24 with the sample 26 to be examined may be situated beneath the electron beam of the particle beam device (examination position, also referred to as the second sample holder position). To assume the examination position, the second sample receptacle 24 may be moved about the receptacle axis 28 in relation to the sample holder 21. In the embodiment described above, the second sample receptacle 24 may be rotated by an angle of 0° to 90° in first direction A and second direction B, starting from the initial position described above.

In a method step S5, the electron beam may then be generated and directed at the sample 26 to be examined, and the resulting interaction particles, e.g., electrons scattered on the sample 26 to be examined, may be detected by the detector 20. In an alternative embodiment, the electron beam may be generated between method steps S3 and S4.

In a method step S6 following method step S5, operating parameters of the TEM 100 may be set. In the embodiment shown here, this may be a calibration of the first magnetic lens 5, the second magnetic lens 6 and/or the third magnetic lens 7 by adjusting the lens currents used for the aforementioned magnetic lenses. Furthermore, the corrector 16 may be set in a suitable manner with the aid of operating parameters.

The adjusted examination position may then be stored in a memory medium (method step S7), that may be a computer-readable storage medium. In a subsequent method step S8, the sample holder 21 may then be moved in such a way that the reference sample 25 in the first sample receptacle 23 is brought under the electron beam (reference position,, also referred to as the first sample holder position). This reference position may then be stored in the memory medium (method step S9). In a method step S10, the electron beam may be directed onto the reference sample 25, and the resulting interaction particles may be detected. The corrector 16 may be arranged by adjusting operating parameters of the corrector 16 to obtain a good image quality (method step S11). The sample holder 21 may then be moved into the examination position stored previously (method step S 12). The electron beam may be next guided onto the sample 26 to be examined, and the resulting interaction particles may be detected. Corresponding detection signals may be used in particular to generate images and diffraction patterns (method step S13).

The corresponding images and diffraction patterns may be stored in the memory medium (method step S14).

In another method step S15, the quality of the resulting images and diffraction patterns may be evaluated. If the quality is inadequate, the method steps S8 through S15 may be run through again, while in the method step S11, the operating parameters of the corrector 16 may be adjusted, so that the quality of the images and diffraction patterns is improved.

If the quality of the images and diffraction patterns is sufficient, the method may be terminated in method step S16.

The method illustrated in FIG. 8 may also be used when the holding device 32 according to FIG. 7A described above or the holding device 35 according to FIG. 7B described above is situated in the sample holder 21, but with the following changes. In the method step S1, the reference sample 25 may be placed on the first sample receptacle 33 of the holding device 32. With the holding device 35 according to FIG. 7B, the reference sample 25 may be placed on the carbon film 39. As an alternative to this, it is provided that the carbon film 39 itself may be the reference sample 25. In the method step S2, the sample 26 to be examined may then be placed in the second sample receptacle 34 of the holding device 32, or on the first web 37A and the second web 37B.

In a method step S2A, which then follows, the holding device 32 or the holding device 35 instead of the sample 26 to be examined may be placed in the second sample receptacle 24 of the sample holder 21. Following that, the method step S3 already described above may be performed (cf. FIG. 8A).

The method step S4 may also be modified slightly in comparison with the embodiment already described above. The sample holder 21 may be moved in such a way that the second sample receptacle 34 or the first web 37A and the second web 37B with the sample 26 to be examined, may be placed beneath the electron beam of the particle beam device (examination position, also referred to as the second sample holder position). To assume the examination position, the second sample receptacle 24 having the holding device 32 or the holding device 35 may be moved about the receptacle axis 28 in relation to the sample holder 21, as already described above.

The method step S8 may also be modified slightly when using the holding device 32 or the holding device 35. In this method step S8, the sample holder 21 may be moved in such a way that the reference sample 25 of the holding device 32 or the holding device 35 may be moved beneath the electron beam (reference position, also referred to as the first sample holder position). All other method steps when using the holding device 32 or the holding device 35 may be the same as those described above with respect to FIG. 8.

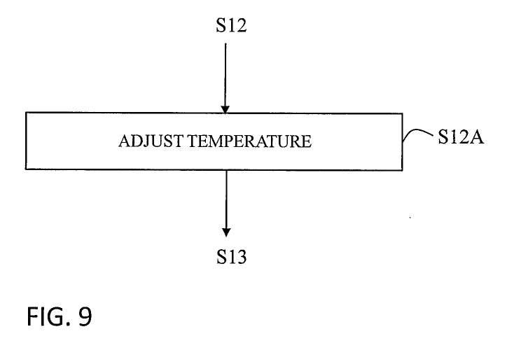

FIG. 9 shows an intermediate step S12A, which may be inserted between the method steps S12 and S13 of the method according to FIG. 8. In the method step S12A, the sample 26 to be examined may be brought to the desired temperature by a heating and/or cooling device. The sample 26 to be examined may then be measured as already described above.

Various embodiments discussed herein may be combined with each other in appropriate combinations in connection with the system described herein. Additionally, in some instances, the order of steps in the flow charts or flow diagrams may be modified, where appropriate. Further, various aspects of the system described herein may be implemented using software, hardware, and/or a combination of software and hardware. Software implementations of the system described herein may include executable code that is stored in a computer readable storage medium and executed by one or more processors. The computer readable storage medium may include a computer hard drive, ROM, RAM, flash memory, portable computer storage media such as a CD-ROM, a DVD-ROM, a flash drive and/or other drive with, for example, a universal serial bus (USB) interface, and/or any other appropriate tangible storage medium or computer memory on which executable code may be stored and executed by a processor. The system described herein may be used in connection with any appropriate operating system.

Other embodiments of the invention will be apparent to those skilled in the art from a consideration of the specification or practice of the invention disclosed herein. It is intended that the specification and examples be considered as exemplary only, with the true scope and spirit of the invention being indicated by the following claims.

What is claimed is:

1. A method for adjusting at least one operating parameter of a particle beam device, wherein a sample holder having at least one first sample receptacle for receiving a reference sample and having at least one second sample receptacle for receiving a sample to be examined with the aid of a particle beam is used in the particle beam device, the method comprising:
placing a reference sample on the first sample receptacle;
placing a sample to be examined with the aid of a particle beam on the second sample receptacle;
moving the sample holder in such a way that the particle beam strikes the reference sample on the first sample receptacle;
adjusting at least one operating parameter of the particle beam device by examining the reference sample with the aid of the particle beam;
moving the sample holder in such a way that the particle beam strikes the sample to be examined on the second sample receptacle; and
examining the sample to be examined with the aid of the particle beam.

2. The method according to claim 1, further comprising:
transferring the sample holder into the particle beam device.

3. The method according to claim 1, wherein the sample holder is moved by at least one of:
rotating the sample holder by a predefinable angle, starting from an initial position of the sample holder, in at least one of: a first sample holder direction and a second sample holder direction; and
moving along a first axis, a second axis and a third axis, the first axis, the second axis and the third axis each being perpendicular to the others, and the third axis being oriented parallel to an optical axis of the particle beam device.

4. The method according to claim 3, wherein the sample holder is rotated about at least one of the following axes: the first axis, the second axis and the third axis by an angle of 0° to 180°.

5. The method according to claim 4, wherein the sample holder is rotated by an angle of 0° to 90°.

6. The method according to claim 1, further comprising:
adjusting an examination position of the second sample receptacle by moving the second sample receptacle in relation to the sample holder.

7. The method according to claim 6, wherein the examination position of the second sample receptacle is adjusted by rotation by an angle of 0° to 180° starting from an initial position of the second sample receptacle.

8. The method according to claim 7, wherein the examination position of the second sample receptacle is adjusted by at least one of: rotation by an angle of 20° to 160° and rotation by an angle of 0° to 90°, starting from the initial position of the second sample receptacle, in at least one of: a first direction and a second direction.

9. The method according to claim 1, wherein the operating parameter is adjusted for calibration of at least one of: an electromagnetic device and an electrostatic device of the particle beam device.

10. The method according to claim 9, wherein the operating parameter is adjusted for calibration of a corrector of the particle beam device.

11. The method according to claim 1, wherein the sample to be examined is brought to a predefinable temperature.

12. A sample holder for holding a sample to be examined with the aid of a particle beam, comprising:
a sample holder body that is movable for assuming a predefinable sample holder position;
at least one first sample receptacle that is immovable in relation to the sample holder body; and
at least one second sample receptacle that is movable in relation to the sample holder body to assume an examination position.

13. The sample holder according to claim 12, wherein the second sample receptacle includes a device for adjusting a predefinable temperature of a sample receivable in the second sample receptacle.

14. The sample holder according to claim 12, wherein the first sample receptacle receives a reference sample, and the second sample receptacle receives the sample to be examined.

15. The sample holder according to claim 12, wherein the sample holder body is movable along a first axis, a second axis and a third axis, the first axis, the second axis and the third axis being perpendicular to each other, and the third axis being parallel to an optical axis of a particle beam device.

16. The sample holder according to claim 15, wherein the sample holder body is rotatable about at least one axis of the following axes: the first axis, the second axis and the third axis and is rotatable by an angle of 0° to 180°

17. The sample holder according to claim 16, wherein the sample holder body is rotatable by an angle of 0° to 90°.

18. The sample holder according to claim 15, wherein the second sample receptacle is rotatable about a receptacle axis, the receptacle axis, starting from an initial position of the second sample receptacle, being situated in or parallel to a plane, which is spanned by two of the following axes: the first axis, the second axis and the third axis.

19. The sample holder according to claim 18, wherein the second sample receptacle is rotatable by a predefinable angle, starting from the initial position of the second sample receptacle.

20. The sample holder according to claim 18, wherein the receptacle axis runs perpendicular to a longitudinal axis of the sample holder, and the second sample receptacle, starting from the initial position, is rotatable by an angle of 0° to 180° in at least one of: a first direction and a second direction.

21. The sample holder according to claim 20, wherein the second sample receptacle is rotatable by an angle of 0° to 90°.

22. The sample holder according to claim 12, further comprising:
an adjustment device that adjusts the examination position.

23. The sample holder according to claim 22, wherein the adjustment device includes a sprocket wheel mechanism.

24. A sample holder for holding a sample to be examined with the aid of a particle beam, comprising:
a sample holder body that is movable for assuming a predefinable sample holder position;
at least one first sample receptacle that is immovable in relation to the sample holder body; and
at least one second sample receptacle having a device for adjusting a predefinable temperature of a sample receivable in the second sample receptacle.

25. The sample holder according to claim 24, wherein the first sample receptacle receives a reference sample, and the second sample receptacle receives the sample to be examined.

26. The sample holder according to claim 24, wherein the sample holder body is movable along a first axis, a second axis and a third axis, the first axis, the second axis and the third axis being perpendicular to each other, and the third axis being parallel to an optical axis of a particle beam device.

27. The sample holder according to claim 26, wherein the sample holder body is rotatable about at least one axis of the following axes: the first axis, the second axis and the third axis and is rotatable by an angle of 0° to 180°

28. The sample holder according to claim 26, wherein the second sample receptacle is rotatable about a receptacle axis, the receptacle axis, starting from an initial position of the second sample receptacle, being situated in or parallel to a plane, which is spanned by two of the following axes: the first axis, the second axis and the third axis.

29. The sample holder according to claim 28, wherein the second sample receptacle is rotatable by a predefinable angle, starting from the initial position of the second sample receptacle.

30. The sample holder according to claim 28, wherein the receptacle axis runs perpendicular to a longitudinal axis of the sample holder, and the second sample receptacle, starting from the initial position, is rotatable by an angle of 0° to 180° in at least one of: a first direction and a second direction.

31. A sample holder for holding a sample to be examined with the aid of a particle beam, comprising:
a sample holder body that is movable to assume a predefinable sample holder position; and
at least one holding device that is movable in relation to the sample holder body to assume an examination position, wherein the holding device includes:
at least one first sample receptacle to receive a reference sample; and
at least one second sample receptacle to receive the sample to be examined.

32. The sample holder according to claim 31, wherein the second sample receptacle includes a device for adjusting a predefinable temperature of a sample receivable in the second sample receptacle.

33. The sample holder according to claim 31, wherein the holding device is situated in a receptacle device that is rotatable about a receptacle axis, the receptacle axis, starting from an initial position of the receptacle device, being situated in or parallel to a plane, which is spanned by two of the following axes: a first axis, a second axis and a third axis.

34. The sample holder according to claim 33, wherein the receptacle device is rotatable by a predefinable angle, starting from the initial position of the receptacle device.

35. The sample holder according to claim 33, wherein the receptacle axis runs perpendicular to a longitudinal axis of the sample holder, and wherein the receptacle device, starting from the initial position, is rotatable by an angle of 0° to 180° in at least one of: a first direction and a second direction.

36. The sample holder according to claim 35, wherein the receptacle device is rotatable by an angle of 0° to 90°.

37. The sample holder according to claim 31, further comprising:
an adjustment device that adjusts the examination position.

38. A sample holder for holding a sample to be examined with the aid of a particle beam, comprising:
a grid-type holding device having a plurality of openings, wherein at least one first opening and at least one second opening are separated from one another by at least one dividing web, and wherein the grid-type holding device includes:
at least one first sample receptacle for receiving a reference sample; and
at least one second sample receptacle for receiving the sample to be examined.

39. The sample holder according to claim 38, wherein the grid-type holding device includes a surface, wherein the surface includes a recess, and wherein the sample to be examined is receivable in the recess.

40. The sample holder according to claim 39, wherein the ratio of the surface to the recess is in a range of 5:1 to 3:1.
